(19) United States
(12) Patent Application Publication
(10) Pub. No.: US 2002/0048939 A1
(43) Pub. Date: Apr. 25, 2002

(54) METHOD OF FABRICATING A MOS TRANSISTOR WITH IMPROVED SILICIDE

(76) Inventor: Robin Lee, Hsinchu Hsien (TW)

Correspondence Address: CHARLES C.H. WU & ASSOCIATES, A PROFESSIONAL CORPORATION, 7700 IRVINE CENTER DRIVE, SUITE 710, IRVINE, CA, 92618-3043, US

(21) Appl. No.: 09/488,303

(22) Filed: Jan. 20, 2000

(30) Foreign Application Priority Data
Dec. 13, 1999 (TW) 88121807

(51) Int. Cl. H01L 21/335; H01L 21/8232; H01L 21/4763; H01L 21/44

(52) U.S. Cl. 438/649; 438/651; 438/655

(57) ABSTRACT

A method of fabricating a MOS transistor. A low step coverage PE-oxide layer is formed between a polygate and a gate spacer. As a result of the characteristic of the PE-oxide layer, an overhang is formed on the top corner of the polygate. A gap, which is broad at the top and narrow at the bottom, is then formed therein by removing a portion of the PE-oxide layer. A salicide process is performed to form a metal silicide layer on the exposed surface of the polygate and the source/drain region of the MOS transistor.

### CROSS-REFERENCE TO RELATED APPLICATION

This application claims the priority benefit of Taiwan application serial no. 88121807, filed Dec. 13, 1999.

### BACKGROUND OF THE INVENTION

1. Field of the Invention

The present invention relates to a method of fabricating a semiconductor device, and more particularly to a method of fabricating a metal-oxide-semiconductor (MOS) transistor.

2. Description of the Related Art

In the manufacturing of deep submicron devices, the level of integration is increased. Hence, line width, contact area and junction depth of all devices are reduced. To improve the quality of devices and to lower transmission delay due to an increase in electrical resistance and capacitance (RC-delay), silicide layers are usually formed over the MOS transistors. The silicide layers are formed over the polygate and the source/drain terminals so that contact resistance at these junctions is lowered. Since there is no need to perform a photolithographic operation, the step of forming silicide layers over the terminals of MOS transistors is often referred to as a self-aligned silicide (Salicide) process. Materials for forming a self-aligned silicide layer include titanium silicide (TiSix) and cobalt silicide (CoSix). Because titanium silicide has the advantage of easy control during fabrication, it is one of the most frequently employed silicide materials.

Titanium silicide layer can be further classified structurally as being in a C49 high-resistance metastable phase (C49-TiSi₂) or in a C54 low-resistance thermodynamically stable phase (C54-TiSi₂). To form a titanium silicide layer, a first stage annealing process is carried out so that titanium in a titanium layer reacts with silicon in a silicon layer. After the first annealing process, C49 phase titanium silicide and a small amount of C54 phase titanium silicide are formed. The unreacted titanium layer is removed, and then a second annealing process is carried out at an elevated temperature. In the second annealing process, the high-resistance C49 phase titanium silicide within the titanium silicide layer is gradually transformed into a low-resistance C54 phase titanium silicide.

C49 phase titanium silicide has a low formation temperature but its electrical resistance is high. In contrast, C54 phase titanium silicide has a low electrical resistance but its formation temperature is high. In general, a rapid thermal process for transforming the high-resistance C49 phase titanium silicide in a titanium silicide layer into low-resistance C54 phase titanium silicide must be employed. Furthermore, in order to form a thick and uniform silicide layer, processing temperature must be raised or the period of heating must be extended.

As dimensions of the polygate are gradually reduced due to miniaturization, the formation temperature of the C54 phase titanium silicide is increased because of the narrow line effect. The narrow line effect refers to the increase in phase transformation temperature resulting from a decrease in line width. In other words, as line width becomes smaller, temperature required to transform high-resistance C49 phase titanium silicide into low-resistance C54 phase titanium silicide is increased. However, raising the rapid thermal processing temperature to obtain C54 phase titanium silicide may result in some instability in the resulting silicide layer. Hence, too high a processing temperature is unsuitable for forming small dimensional devices. Moreover, reaction temperature is difficult to control and may result in lateral growth of the silicide layer. In addition, as the level of integration continues to increase and separation between neighboring devices continues to decrease, lateral growth can easily lead to bridging between a gate terminal and a source/drain terminal. To prevent such bridging, an upper limit to the temperature for forming a metal silicide layer must be set. However, this will result in an intensification of the narrow line effect. Hence, a higher resistance will be formed at the polygates.

### SUMMARY OF THE INVENTION

The present invention provides a method of fabricating a MOS transistor adapted for a semiconductor substrate. A polygate is formed on the substrate. A lightly doped drain (LDD) region is formed on both sides of the polygate. A low step coverage plasma-enhanced oxide (PE-oxide) layer is deposited over the substrate. A spacer material layer, such as a silicon nitride layer, is formed on the PE-oxide layer. A portion of the spacer material layer is then removed to form a gate spacer on the sidewall of the gate. The PE-oxide layer on the polygate and substrate and a portion of the PE-oxide layer between polygate and the gate spacer are both removed by anisotropic dry etching to form a gap therein. Since the PE-oxide layer has an overhang on the top corner of the polygate, the gap is broad at the top and narrow at the bottom. A source/drain region is formed on both sides of the gate spacer. A salicide process is performed to form a metal silicide layer on the exposed surface of the polygate and the source/drain region.

In the invention, a gap is formed between the polygate and the gate spacer, and the exposed area of the polygate is therefore increased. Consequently, a problem of high resistance because of the narrow line effect can be resolved. Furthermore, since the gap has a broad width at the top and has a narrow width at the bottom, the lateral growth of the silicide layer formed on the gate can be stopped, and thus a bridging between the gate terminal and the source/drain terminal can be prevented.

It is to be understood that both the foregoing general description and the following detailed description are exemplary and explanatory only and are not restrictive of the invention, as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIGS. 1A-1E are schematic, cross-sectional views illustrating fabrication of a MOS transistor according to one preferred embodiment of the present invention; and

FIG. 2 is an enlargement of area 200 in FIG. 1C.

### DESCRIPTION OF THE PREFERRED EMBODIMENTS

Reference will now be made in detail to the present preferred embodiment of the invention, examples of which are illustrated in the accompanying drawings. Wherever possible, the same reference numbers are used in the drawings and the description to refer to the same or like parts.

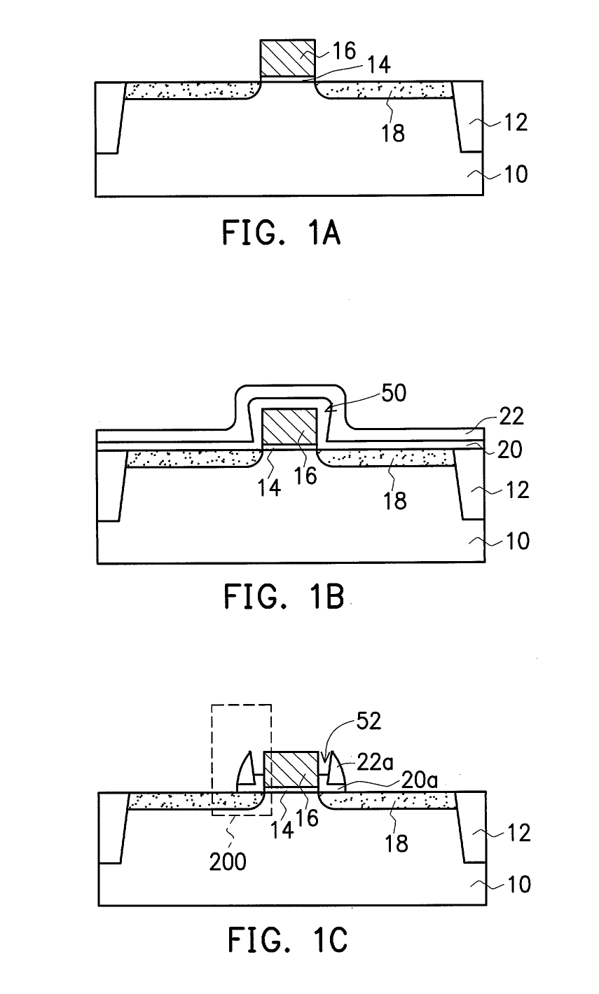

Referring to FIG. 1A, a semiconductor substrate 10 is provided. A semiconductor device isolation structure, such as shallow trench isolation (STI) 12, is formed therein. A polygate is formed on the substrate 10, wherein the polygate is a stack of a silicon oxide layer 14 and a polysilicon layer 16. A lightly doped drain (LDD) region 18 is then formed in the substrate 10 and on both sides of the polygate. Since foregoing structure is well known to those skilled in the art, the method of fabrication will not describe any more.

Referring to FIG. 1B, a plasma-enhanced oxide (PE-oxide) layer 20 of about 100 angstroms is deposited over the polygate and the substrate 10 by plasma enhanced chemical vapor deposition (PECVD) at a temperature lower than about 500° C. and a pressure of about 1 atm. The PE-oxide layer 20 formed under these conditions has a low step coverage, and thus an overhang 50 is formed on the top corner of the polygate. Hence, the portion of the PE-oxide layer 20 formed on the sidewall of the polygate has a broad width at the top and has a narrow width at the bottom.

A spacer material layer 22 is then formed on the PE-oxide layer 20. The spacer material layer 22 must have an etching selectivity to the PE-oxide layer 20. For example, the spacer material layer 22 can be a silicon nitride layer made by low pressure chemical vapor deposition (LPCVD).

Referring to FIG. 1C, a spacer etch back process is carried out by using anisotropic dry etching, such as reactive ion etching (RIE) technology, to remove the spacer material layer 22 on the polygate and the substrate 10, and thus a gate spacer 22a is formed on the sidewall of the polygate. The portion of the PE-oxide 20 on the sidewall of the polygate is located between the polygate and the gate spacer 22a. Then, the PE-oxide layer 20 is etched by changing the etching recipe, for example by using fluorocarbon (CF_{X}). The part of the PE-oxide layer 20 on the polygate and on the substrate 10 is removed, and a portion of the PE-oxide layer 20 between the polygate and the gate spacer 22a is removed to form a gap 52 therein. The residual part of the PE-oxide layer 20 serves as a buffer layer to release stresses from the gate spacer 22a. Since the gap 52 is formed beside the polysilicon layer 16, the sidewall surface of the polysilicon layer 16 is exposed, and the exposed area of the polysilicon layer 16 is therefore increased.

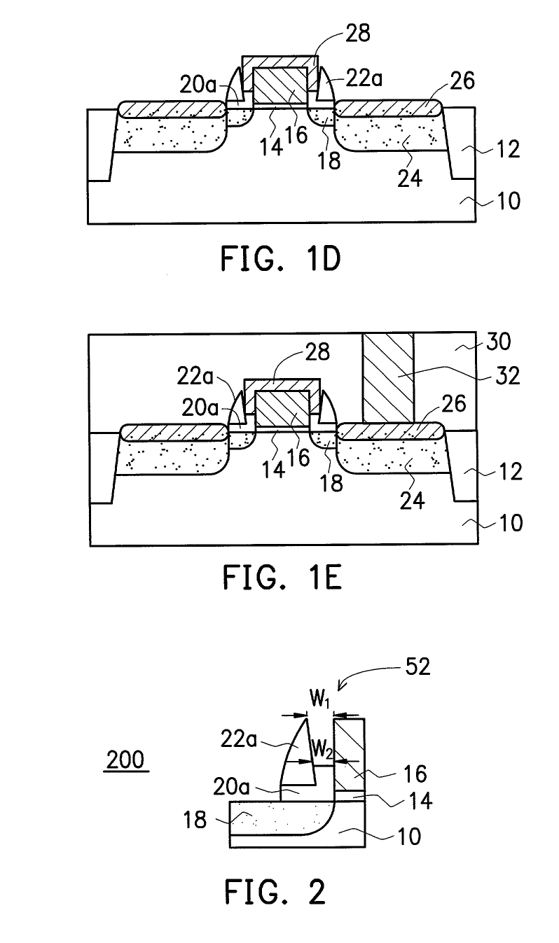

FIG. 2 is a local enlargement of area 200 in FIG. 1C. Referring to FIG. 2, the gap 52 is formed between the polysilicon layer 16 and the gate spacer 22a. The gap 52 has a broad width at the top and has a narrow width at the bottom; i.e. the top width (w1) of the gap 52 is wider than the bottom width (w2).

Referring to FIG. 1D, a source/drain region 24 is formed in the substrate 10 and on both sides of the polygate by, for example, ion implant technology. A self-aligned silicide (Salicide) process is then employed to form metal silicide layers 26 and 28 on the exposed surfaces of the polygate (e.g. polysilicon layer 16) and the source/drain region 24, respectively. A material of the metal silicide layers 26 and 28 comprise, for example, titanium silicide (TiSi_{X}) or cobalt silicide (CoSi_{X}). If the metal silicide layers 26 and 28 are titanium silicide layers, the silicide layers 26 and 28 are formed by following exemplary steps. First, a titanium layer is formed over the substrate 10 by sputtering. A first annealing operation is then performed so that the titanium and the silicon at their junction interface react to form a mainly C49 phase constituted titanium silicide layer. The unreacted titanium layer is removed by a wet dip such as a RCA solution composed of ammonium hydroxide (NH₄OH), hydrogen dioxide (H₂O₂), hot de-ionization water (HDIW), etc. A second annealing operation is then performed so that the original high-resistance C49 phase titanium silicide is transformed into a low C54 phase titanium silicide.

Due to the presence of the gap 52 between the polysilicon layer 16 and gate spacer 22a, the exposed area of the polysilicon layer 16 is increased. Consequently, area coverage of silicide over the polygate is increased, and the problem of high resistance caused by the narrow line effect can be minimized. In addition, since the gap 52 has a sloped profile, it promotes the formation of silicide. Furthermore, if the thickness of the metal silicide layer 28 is thinner than the top width (w1) of the gap 52, the metal silicide layer cannot grow over the gate spacer 22a. Hence, lateral growth of the metal silicide layer 28 can be minimized, and thus a bridge between the polygate and source/drain can be prevented.

Referring to FIG. 1E, an insulating layer 30 is formed over the substrate 10 to serve as interlayer dielectrics (ILD). The insulating layer 30 is made by, for example, depositing a silicon oxide layer, and then coating a low-k material such as spin-on glass (SOG) or spin-on polymer (SOP), etc. on the silicon oxide layer. A conductive plug 32 is formed in the insulating layer 30 and is electrically connected to the metal silicide layer 26. The conductive plug 32 is formed by using photolithography and etching technology to form an opening, and then filling the opening with conductive material to form the conductive plug 32.

According to the embodiment of the invention, the formation area of the silicide layer on the polygate is increased, and a problem of high resistance caused by the narrow line effect can be minimized. Moreover, a bridge between the polygate and source/drain terminals can be prevented.

It will be apparent to those skilled in the art that various modifications and variations can be made to the structure and the method of the present invention without departing from the scope or spirit of the invention. In view of the foregoing, it is intended that the present invention cover modifications and variations of this invention provided they fall within the scope of the following claims and their equivalents.

What is claimed is:

1. A method of fabricating a MOS transistor adapted for a semiconductor substrate, the method comprising:
forming a polygate on the substrate;
forming a LDD region on both sides of the polygate;
forming a PE-oxide over the substrate;
forming a spacer material layer on the PE-oxide layer;
removing a portion of the spacer material layer to form a gate spacer on a sidewall of the polygate;
removing a portion of the PE-oxide layer on the polygate and substrate and removing a portion of the PE-oxide layer between the polygate and the gate spacer to form a gap therein;
forming a source/drain region on both sides of the gate spacer; and
performing a salicide process to form a metal silicide layer on an exposed surface of the polygate and the source/drain region.

2. The method according to claim 1, wherein the polygate is a stack of a silicon oxide layer and a polysilicon layer.

3. The method according to claim 1, wherein the PE-oxide layer is made by plasma enhanced chemical vapor deposition.

4. The method according to claim 1, wherein a material of the spacer material layer comprises silicon nitride.

5. The method according to claim 1, wherein the step of removing the PE-oxide layer includes anisotropic dry etching.

6. The method according to claim 1, wherein a gap width at the top is wider than the gap width at the bottom.

7. The method according to claim 1, wherein the metal silicide layer comprises a titanium silicide layer.

8. The method according to claim 1, wherein the metal silicide layer comprises a cobalt silicide layer.

9. A method of fabricating a gate structure adapted for a semiconductor substrate, the method comprising:
forming a polygate on the substrate;
forming a PE-oxide layer over the substrate;
forming a spacer material layer on the PE-oxide layer;
removing a portion of the spacer material layer to form a gate spacer on a sidewall of the polygate;
removing a portion of the PE-oxide layer on the polygate and substrate and removing a portion of the PE-oxide layer between the polygate and the gate spacer to form a gap therein; and
performing a salicide process to form a metal silicide layer on an exposed surface of the polygate.

10. The method according to claim 9, wherein the polygate is a stack of a silicon oxide layer and a polysilicon layer.

11. The method according to claim 9, wherein the PE-oxide layer is made by plasma enhanced chemical vapor deposition.

12. The method according to claim 9, wherein a material of the spacer material layer comprises silicon nitride.

13. The method according to claim 9, wherein the step of removing the PE-oxide layer includes anisotropic dry etching.

14. The method according to claim 9, wherein the gap width at the top is wider than the gap width at the bottom.

15. The method according to claim 9, wherein the metal silicide layer comprises a titanium silicide layer.

16. The method according to claim 9, wherein the metal silicide layer comprises a cobalt silicide layer.
